(19) United States
(12) Patent Application Publication
(10) Pub. No.: US 2003/0040130 A1
(43) Pub. Date: Feb. 27, 2003

(54) Method for selection of parameters for implant anneal of patterned semiconductor substrates and specification of a laser system

(76) Inventors: Abhilash J. Mayur, Salinas, CA (US); Mark Yam, Monte Sereno, CA (US); Paul G. Carey, Mountain View, CA (US); William Schaffer, Atascadero, CA (US)

Correspondence Address: APPLIED MATERIALS, INC., 2881 SCOTT BLVD. M/S 2061, SANTA CLARA, CA, 95050, US

(21) Appl. No.: 09/927,247

(22) Filed: Aug. 9, 2001

(51) Int. Cl. H01L 21/66

(52) U.S. Cl. 438/14

(57) ABSTRACT

A modeling method to identify optimum laser parameters for pulsed laser annealing of implanted dopants into patterned semiconductor substrates is provided. The modeling method provides the optimum range of wavelength, pulse length, and pulse shape that fully anneals the implanted regions while preserving the form and function of ancillary structures. Improved material parameters for the modeling are identified. The modeling method is used to determine an experimental verification method that does not require a fully equipped laser processing station. The model and verification are used to specify an optimum laser system that satisfies the requirements of large area processing of silicon integrated circuits. An alexandrite laser operating between 700 nm and 810 nm with a pulse length of 5 ns to 20 nS is identified for implant anneal of shallow dopants in silicon.

### BACKGROUND OF THE INVENTION

1. Field of the Invention

This invention is directed to methods for improving the implant anneal step in semiconductor integrated circuit (IC) manufacturing. Analytical methods are provided for improving pulsed laser annealing parameters in the activation of implanted dopants on patterned semiconductor substrates. Experimental methods for refining model parameters and verification of model predictions are provided.

2. Description of the Related Art

The manufacture of modern logic, memory, or linear integrated circuits (ICs) typically requires more than four hundred process steps. A number of these steps are thermal processes that raise the temperature of a semiconductor wafer to a target value to induce rearrangements in the atomic order or chemistry of thin surface films (e.g., diffusion, oxidation, recrystallization, salicidation, densification, flow).

Ion implantation is a preferred method for introduction of chemical impurities into semiconductor substrates to form the pn junctions necessary for field effect or bipolar transistor fabrication. Such impurities include p-type dopants such as boron (B), aluminum (Al), gallium (Ga), beryllium (Be), magnesium (Mg), and zinc (Zn) and N-type dopants such as phosphorus (P), arsenic (As), antimony (Sb), bismuth (Bi), selenium (Se), and tellurium (Te). Ion implantation of chemical impurities disrupts the crystallinity of the semiconductor substrate over the range of the implant. At low energies, relatively little damage occurs to the substrate. However, the implanted dopants will not come to rest on electrically active sites in the substrate. Therefore, an “anneal” is required to restore the crystallinity of the substrate and drive the implanted dopants onto electrically active crystal sites. As used herein, “annealing” refers to the thermal process of raising the temperature of an electrically inactive implanted region from an ambient temperature to a maximum temperature for a specified time and cooling to ambient temperatures for the purpose of creating electrically active regions in a device. The result of such annealing and/or the annealing process is sometimes also referred to as “implant annealing,” “activation annealing,” or “activation.”

FIGS. 1A and 1B illustrate a MOSFET structure 150 in cross section and plan view, respectively, immediately prior to implant anneal. The transistor area is defined by the perimeter of the shallow trench isolation (STI) structure 112. The gate structure 102 and local interconnect wiring 160 are deposited and patterned, and the source and drain extension (SDE) regions 140 are implanted. Ideally, the implant anneal is designed to electrically activate 100% of the implanted dopants in regions 140 while uniformly distributing them within a shallow surface region that extends a prescribed distance under the gate structure. The available drain current from the fully fabricated MOSFET is increased if, 1) the concentration of electrically active impurities within the SDE region is uniform and high (>10²⁰ cm⁻³) and, 2) the concentration of impurities falls abruptly at the boundary of the SDE (<2 nm/decade of concentration). An abrupt impurity profile is especially desired in the extension region 106 under the gate structure 102.

Two important parameters associated with the implant anneal step determine the distribution of dopants in SDE regions 140: (i) the maximum temperature during implant anneal and (ii) the duration of the implant anneal. For the pn junction depths required for modern silicon CMOS ICs, the implant anneal is improved if the maximum temperature during the anneal is greater than 1300K for a duration of less than 50 mS.

The current art in implant anneal technology employs batch furnaces, fast ramp furnaces, or rapid thermal processor (RTP) approaches. These techniques exploit optical absorption processes in semiconductors over a broad band of optical and infrared wavelengths and, by design, heat the entire wafer uniformly. Due to the response time of the radiation sources used and the inherent thermal mass of the semiconductor substrate, the minimum characteristic thermal process time associated with these techniques is greater than one second. Fast diffusion processes occurring during this time, such as transient enhanced diffusion, drive dopants deeper into the substrate than desired and result in a graded dopant concentration at the perimeter of the profile. Both effects are deleterious to device performance.

It is well known in the art that pulsed laser annealing (PLA) recrystallizes and activates implanted dopants in unpatterned semiconductors at high surface temperatures in a time less than 100 nanoseconds (nS). Pulsed laser annealing has been applied to the planar layer case, which is defined as homogeneous semi-infinite layered structures, in a variety of material systems applicable to integrated circuit manufacture. The recrystallization of implant damaged unpatterned substrate and activation of implanted dopants is demonstrated to occur over a wide wavelength range (248 nm<λ<10.6 um), pulse length (1 nS<tp<continuous), and for a variety of pulse shapes, such as rectangular, triangular, and gaussian. By increasing the pulse intensity, the temperature of the surface of the implanted region is raised above the melting point to induce brief periods of surface melting. The depth of the melt and the duration are controlled by the parameters associated with the laser irradiation process, such as wavelength, pulse length, intensity, and temporal pulse shape.

Pulse laser annealing of implanted semiconductors using the surface melting approach shows a higher activation percentage (>2×) and more abrupt profiles (<3 nm/decade of concentration) than the best known methods in rapid thermal processing. Pulse laser annealing of implants, where the maximum surface temperature is less than the melting temperature, also demonstrates recrystallization and activation. For this “submelt” approach, however, thermodynamic constraints and the abruptness of the as-implanted dopant profile limit the achievable concentration of electrically active impurities and the abruptness of the electrically active dopant profile, respectively. This indicates that, for modern integrated circuits, execution of implant anneals for source drain extension and contact formation by either melt or submelt pulsed laser annealing promises to improve transistor performance over the best known methods in rapid thermal processing.

The introduction of pulsed laser annealing into integrated circuit fabrication, however, has proven problematic. In practice, ancillary structures adjacent to source drain extension regions 140, such as gate 102 of FIG. 1A, do not survive laser irradiation using wavelengths and pulse lengths that have been used in the art for PLA.

The problems associated with source drain extension 140 annealing after a source drain extension implant step in complementary MOS (CMOS) processing are illustrative of the difficulty with known PLA methods. At the source drain extension anneal step, other structures, also referred to as ancillary features, exist on the silicon substrate adjacent to the source drain extension regions 140 targeted for anneal, as shown in FIGS. 1A and 1B. The goal of pulsed laser annealing of the source drain extension 140 by pulsed laser annealing is to fully anneal the disordered, implanted regions 140 (FIG. 1B) while preserving the form and function of adjacent structures such as gate 102, shallow trench isolation 112, and poly/STI 160.

A minimum laser intensity is required to anneal source drain extension regions 140 by pulsed laser annealing. Neighboring structures are exposed to the identical laser intensity. Their response to the incoming radiation is the same as the targeted source drain extension regions 140. That is, the incident laser radiation is absorbed by such structures and incident light energy is quickly converted to heat energy. If the ancillary structures reach temperatures above their melting point, the structures catastrophically melt, deform, or delaminate from the substrate. The event is illustrated schematically by comparing FIGS. 1A and 1C. FIG. 1A shows a gate 102 between a shallow source and drain and a polysilicon local interconnect 160 that is routed over an STI structure 112. FIG. 1C shows the same MOSFET structure 150 after the structure has been subjected to a prior art laser annealing protocol. Formerly crystalline region 170 is melted, resulting in delamination of shallow trench isolation structures and gate 102 and interconnect 160 are melted as well. If the intensity of the laser pulse is reduced too much in an effort to preserve other features, the extension of the source drain extension region 140 under gate 106 is incompletely annealed.

The optical and thermal properties of each structure (SDE 140, gate 102, STI 112, and poly/STI 160) determine their relevant response to pulsed laser annealing. Each of these structures, SDE 140, gate 102, STI 112, and poly/STI 160, may be described as a stack of layers. The thermal conductivity and heat capacity of each layer in the stack yields effective values for the thermal resistance and thermal diffusion length of the stack. These properties are strongly dependent on the wavelength of the incident laser radiation. Furthermore, the maximum temperature reached by each structure depends on the pulse shape and pulse length of the laser. In order to utilize the unique capabilities of the pulsed laser annealing approach for implant annealing, suitable laser annealing protocols must be identified from the vast wavelength—pulse length—pulse shape—intensity parameter space. These suitable pulsed laser annealing protocols must fully anneal source drain extension regions 140 without destroying other features on the substrate 150.

A “protocol” for a pulsed laser annealing process is defined by specifying the laser wavelength, pulse length, temporal pulse shape, and intensity used in the pulsed laser annealing processing step. The wavelength is determined by the choice of lasing medium and the properties of the optical cavity used to house the lasing medium in the laser. The pulse length is largely determined by the physical properties of the lasing material and is usually specified by the full width at half maximum intensity (FWHM) of the pulse power as a function of time (nS). The temporal pulse shape is also determined by the laser material but, to a degree, can be engineered. Typical temporal pulse shapes range from triangular to gaussian to rectangular. The intensity of the pulse is usually specified in terms of the energy density in units of joules per square centimeter (J/cm²). The energy density is calculated by integrating the pulse power over the pulse shape as a function of time. Thus, “energy density” determines the “dose” or “fluence” of the laser pulse in terms of the total optical energy delivered per unit area to the target. Notably, the peak laser power during the pulse can only be determined if the temporal pulse shape is known.

Associated with a pulsed laser annealing protocol for the source drain extension 140 anneal process is a “process window.” The “process window” is defined as the difference between the lowest threshold energy density for structural damage to any ancillary structure, such as gate 102, shallow trench isolation region 112, or poly/STI 160 (FIG. 1A), minus the energy density required for full implant anneal of the target area. Typically, the target area is source drain extension region 140 (FIG. 1A).

Useful protocols have non-negative process windows. A non-negative process window is any process window where the energy density required to fully anneal the target area is less than the lowest threshold energy density resulting in structural damage to any ancillary structure on the substrate. A suitable laser annealing protocol will maximize the process window. Since a pulsed laser annealing protocol and its associated process window are associated with the specifics of the composition and geometry of a particular pattern on the substrate, the pulsed laser annealing protocol used to anneal implanted regions in each new integrated circuit will need to be optimized. Such optimization is performed using mathematical modeling approaches and/or physical experimentation. However, both mathematical modeling and physical experimentation approaches are problematic.

The identification of pulsed laser annealing protocols with non-negative process windoews using physical experimentation, for any given patterned substrate, is problematic because it requires the use of capital intensive equipment. For a given installation, pulsed laser annealing parameters cannot be conveniently varied over a sufficiently wide range of the wavelength—pulse length—pulse shape—intensity parameter space. Different wavelengths require different lasers and commercially available lasers. Furthermore,. The laser must be able to generate sufficient pulse energy to anneal the full surface area of the integrated circuit. Because modern integrated circuits have a surface area of at least 6 cm², the laser typically must deliver a pulse energy on the order of 10 joules or more. Lasers capable of delivering such a pulse energy are not available for the majority of wavelengths of interest. Further, the temporal pulse profile of available laser systems can be shortened only at the expense of maximum available pulse energy. Any physical pulsed laser annealing experiment provides only a narrow snapshot of the dynamics of the multi-variable search for a suitable laser annealing protocol. Because of this, physical experimentation is an impractical approach for identifying an optimum pulsed laser annealing protocol for any given patterned substrate.

The identification of pulsed laser annealing protocols with non-negative process windows using mathematical modeling, for any given patterned substrate, is also problematic. Historically, the thermal response of multi-layer stacks of materials to pulsed laser excitation has been modeled using finite element analysis (FEA). The unpatterned case has received the most attention. The modeling is begun by first accumulating best estimates for the thermal and optical properties of each layer in the stack over the required temperature range at the wavelength of interest. Optical absorption is treated using Beer's Law and the Fourier heat equation is used to describe the heat flow. The nonequilibrium kinetics of melting and recrystallization are described phenomenologically as follows. Once an element in the grid array reaches its melting temperature, the velocity of the melt-solid interface is assumed to be proportional to the difference between the interface temperature and the melting temperature. Such calculation may be performed using a software package such as “Laser Induced Melting Prediction” (LIMP), which was developed by M. O. Thomson at Cornell and P. Smith at Harvard. The goal of software, such as LIMP, is to calculate the time evolution of the temperature profile into the depth of the substrate in response to a pulse of laser radiation at a specific wavelength. LIMP, as well as equivalent software packages, simulates one-dimensional heat flow during pulsed laser heating of multi-layer stacks and accounts for the propagation of phase fronts (liquid-solid interface dynamics).

The drawback with prior modeling efforts is that they have not satisfactorily described the physical properties of patterned semiconductor substrates at the temperatures, wavelengths, and intensities associated with laser annealing protocols. Most modeling results do not accurately account for cases involving areas of different materials or layer geometries. Further, model parameters are usually adjusted to fit current experimental arrangements and are typically not appropriate to determine material response at, for example, a different wavelength. Therefore, any prediction about protocols and margins made by such modeling efforts is unsatisfactorily inaccurate for the current purpose.

Known pulsed laser annealing protocols for source drain extension anneal have a propensity for collateral damage. Undirected experimentation is expensive. Existing mathematical modeling capabilities are unsatisfactory. An improved method is required that identifies optimum pulsed laser annealing protocols for the case of source drain extension anneal in integrated circuit fabrication.

### SUMMARY OF THE INVENTION

The current invention improves the performance of pulsed laser annealing (PLA) processes for implant anneal steps used in the manufacture of integrated circuits on patterned semiconductor substrates. In particular, conditions for performing an implant anneal are identified. The implant anneal is required for the activation of source and drain extension (SDE) regions of a MOSFET device fabricated on a silicon substrate.

The instant invention provides a systematic modeling approach that identifies the pulsed laser annealing parameters that fully activate implanted regions of a patterned semiconductor substrate while preserving adjacent structures on the substrate. The pulsed laser annealing parameters comprise wavelength, pulse length, pulse shape, and pulse energy. Using improved optical and material parameters that describe the patterned semiconductor substrate, the model approach accurately predicts the pulse energy density required to fully anneal implanted regions of a patterned substrate. By applying this energy density to one-dimensional reductions of the actual three-dimensional ancillary stacks on the substrate, such as gate 102, and poly/STI, the modeling approach of the instant invention predicts whether the adjacent structures melt at the energy required for implant anneal processing. The use of one-dimensional reductions of the actual three-dimensional ancillary stacks on the substrate is an advantageous aspect of the instant invention. The model results of the instant invention indicate that process window is improved for a particular structure when the pulse length at a given wavelength is reduced. Further, a minimum wavelength is predicted where no reduction in pulse length results in a positive process window.

Another unique aspect of the modeling efforts of the instant invention is the advantageous use of physical experiments. The results of physical experiment are used for two purposes. First, the results are used to improve and verify the values used to describe the physical parameters of the patterned semiconductor substrate. These improved physical parameters lead to improved modeling predictions. Second, the results of physical experiments are used to verify the predictions made by the modeling experiments.

One aspect of the present invention provides a method for modeling an annealing protocol for an implant anneal of a patterned semiconductor substrate. The method comprises the step of accumulating optical and thermal parameters for each sublayer in a plurality of vertically unique one-dimensional layer structures in the patterned semiconductor substrate, the plurality of vertically unique one-dimensional layer structures including a one-dimensional target layer structure and at least one one-dimensional ancillary layer structure. Next, an energy density required for full anneal of said one-dimensional target layer structure is determined using the annealing protocol. Finally, for each sublayer of a one-dimensional ancillary layer structure in said plurality of vertically unique one-dimensional layer structures, an evaluation is made as to whether a temperature reached in the sublayer exceeds the sublayer melting temperature during the annealing protocol when the energy density required for full anneal of said one-dimensional target layer structure is used.

Using the techniques of the instant invention, it has been unexpectedly discovered that, in the case of shallow drain extension annealing in silicon integrated circuit manufacturing, the alexandrite laser, having a pulse length of 5 nS-20 nS and a pulse energy approaching 10J or greater, is suitable for such applications. One embodiment of the present invetion provides a pulsed alexandrite laser system for use in shallow source drain annealing of silicon CMOS substrates having a technology node of 100 nm or less. The laser system is characterized by a full width half maximum pulse length selected from the range of 5 nanoseconds to 20 nanoseconds and an output pulse energy of greater than 6 joules per pulse.

### BRIEF DESCRIPTION OF THE DRAWINGS

FIGS. 1A and 1B, respectively, illustrate a MOSFET structure in cross section and in plan view whereas FIG. 1C illustrates a cross section after irradiation with a prior art laser annealing protocol.

FIGS. 2A-2F are cross sectional views of a method for forming and annealing implanted SDE regions of a typical MOSFET structure.

FIGS. 3A and 3B show the wavelength and temperature dependence of the imaginary and real parts of the complex index of refraction for crystalline silicon, respectively.

FIG. 4 illustrates model results for the pulse length dependence of the critical energy densities at 748 nm for implant anneal, gate melting, and poly/STI melting assuming a particular set of material parameters.

FIG. 5 shows the results of model calculations for a laser wavelength of 748 nm and near-rectangular pulse shape with a full width half maximum pulse length of 20 nS.

FIG. 6 shows cross-sectional transmission electron microscope micrographs of an amorphized silicon surface that has been annealed using two different energy densities using a laser protocol having a wavelength of 532 nm, a near gaussian pulse profile, and a full width half maximum pulse length of 18 nS.

FIG. 7 shows the results of secondary ion mass spectroscopy measurements for the boron impurity profile of an amorphized silicon surface implanted with 1E¹⁵ cm^{-2 11}B before and after pulsed laser annealing using a laser annealing protocol having a wavelength of 532 nm, a near gaussian pulse profile, a full width half maximum pulse length of 18 nS FWHM, and a pulse energy of 0.54J/cm².

FIG. 8 shows the results of secondary ion mass spectoscopy and sheet resistance measurements for the junction depth and sheet resistivity dependence on energy density for a laser annealing protocol having a wavelength of 532 nm, a near gaussian pulse profile, and a full width half maximum pulse length of 18 nS FWHM

FIG. 9 illustrates the experimental configuration used to perform physical experiments in accordance with one embodiment of the present invention.

FIG. 10 illustrates representative time resolved reflectivity signals using a 1.5 μm InGaAs probe laser (cw) during pulsed laser annealing from an amorphized silicon substrate irradiated with near-rectangular, 20 nS FWHM pulses at 748 nm at different energy densities used to compare experimental results to model predictions made by one embodiment of the present invention.

FIG. 11 illustrates time resolved reflectivity and transmission measurements using a 1. μum InGaAs probe laser (cw) during pulsed laser annealing from a polySi (120 nm)/SiO₂ (292 nm)/Si (001) layer stack using a near-rectangular, 20 nS FWHM pulses at 748 nm.

FIG. 12 shows the results, at three different energy densities, of time resolved reflectivity and transmission measurements for 1.5 μm laser light (cw) incident on a SiO₂ (292 nm)/Si (001) stack during 748 nm laser annealing with a pulse length of 20 ns.

Like reference numerals refer to corresponding parts throughout the several views of the drawings.

### DESCRIPTION OF THE PREFERRED EMBODIMENTS

I. The Patterned Semiconductor Manufacturing Process

The current invention is applied to the manufacture of patterned semiconductor nodes. In some embodiments of the present invention, the patterned semiconductor node has a technology node of 100 nm or less. As used herein, the term “technology node” is in accordance with the definition for Technology node provided in The International Technology Roadmap for Semiconductors (2000 Update), published by the Semiconductor Industry Association (SIA), San Jose Calif.; http://public.itrs.net/.

The current invention improves the performance of the implant anneal steps used in the manufacture of integrated circuits on semiconductor substrates. Generally, the methods of the present invention may be used to anneal selected regions of a large class of materials. The substrates can be any material that has some natural electrical conducting ability. This includes the elemental semiconductors, silicon and germanium, as well as other compounds that exhibit semiconducting properties. Such semiconductor compounds generally include group III-V and group II-VI compounds. Representative group III-V semiconductor compounds include, but are not limited to, gallium arsenide, gallium phosphide, and gallium nitride. Additional semiconductor compounds in accordance with the present invention are found in Van Zant, Microchip Fabrication (McGraw-Hill, New York, 2000), pp. 31-32.

The semiconductor substrates of the present invention include bulk semiconductor substrates as well as substrates having deposited layers. To this end, the deposited layers in some semiconductor substrates processed by the methods of the present invention are formed by either homoepitaxial (e.g. silicon on silicon) or heteroepitaxial (e.g. GaAs on silicon) growth. For example, the methods of the present invention may be used with gallium arsenide and gallium nitride substrates formed by heteroepitaxial methods. Similarly, the invented methods can also be applied to form integrated devices, such as thin-film transistors (TFTs), on relatively thin crystalline silicon layers formed on insulating substrates (e.g., silicon-on-insulator [SOI] substrates). As such, the SOI substrates may be partially depleted or fully depleted.

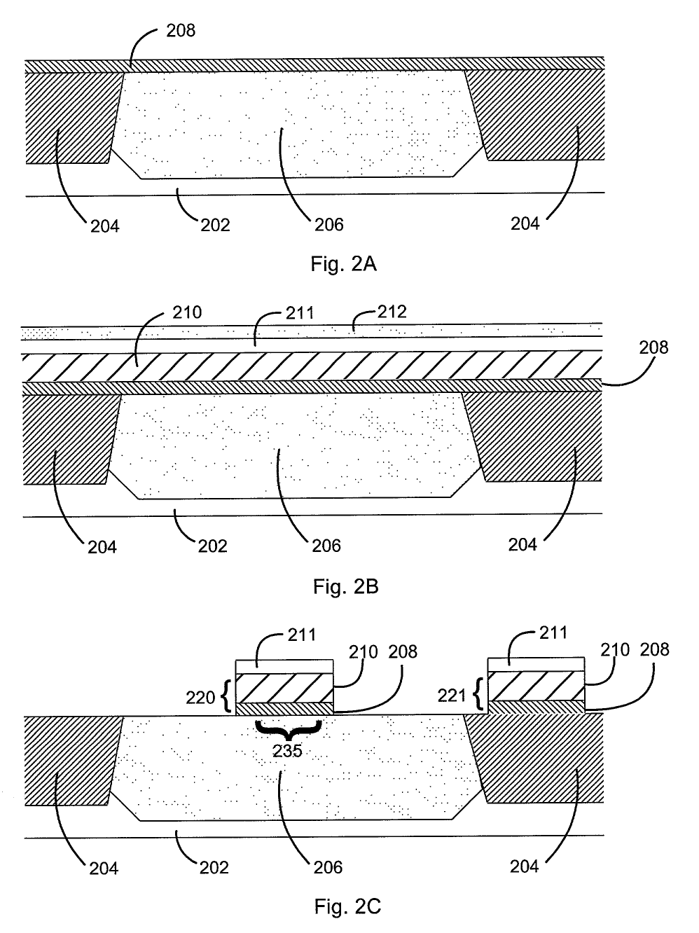

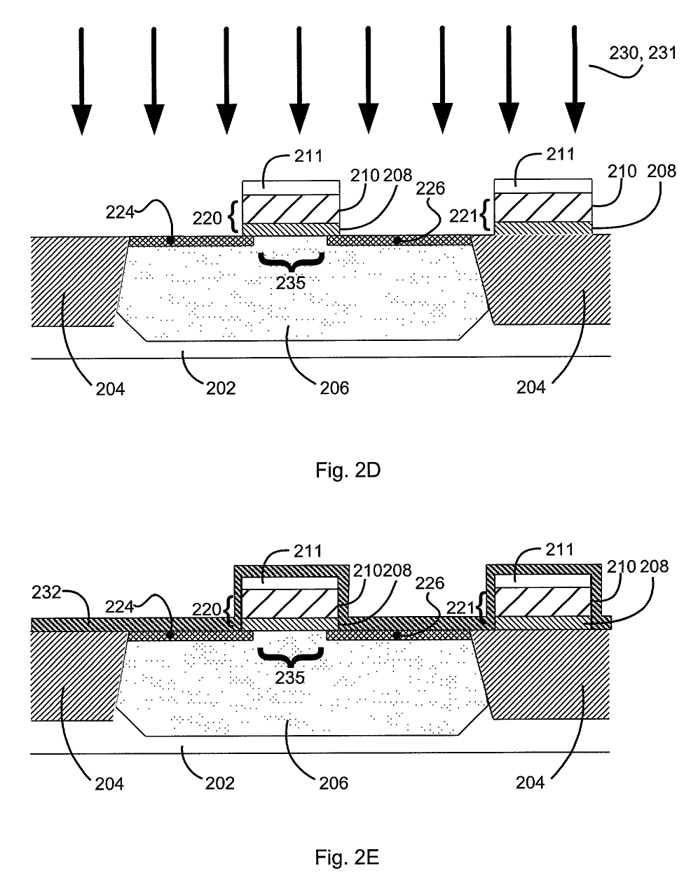

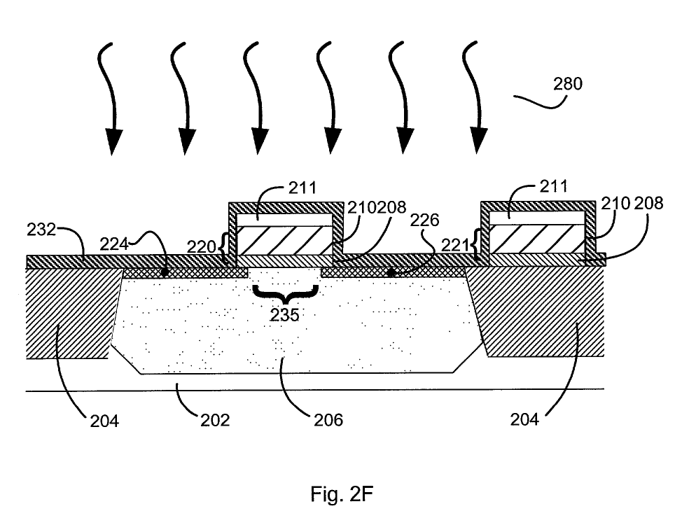

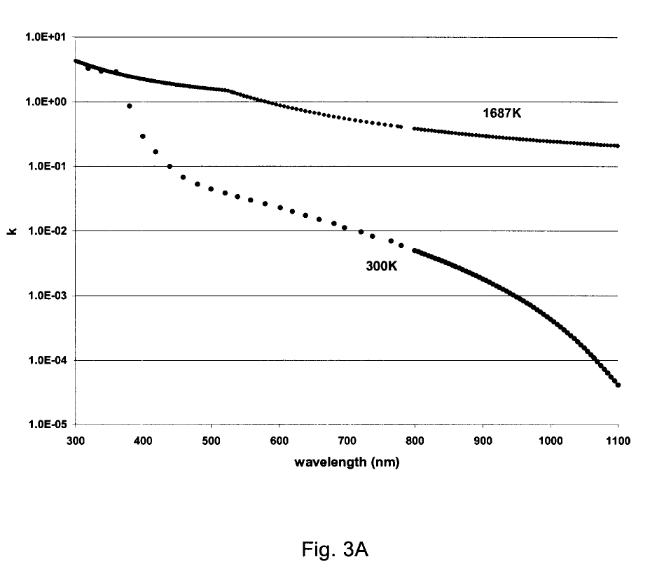

The application of the current invention to the manufacture of an integrated circuit is now illustrated by specific example. In particular, a method for activation annealing of the source and drain extension (SDE) regions of a MOSFET device fabricated on a silicon substrate is presented with reference to FIGS. 2A through 2F. Other process steps in the manufacturing sequence of this specific device also benefit from the current invention but are not illustrated. These include, but are not limited to, source and drain contact annealing, salicidation, or formation of thin-film transistors on the passivation layer.

Referring to FIG. 2A, the integrated device is formed on a bulk silicon semiconductor substrate 202 with appropriate crystallographic orientation, e.g., <001>. For clarity, the thickness of the silicon substrate is not shown to scale in the figures. In practice, the transistor devices are formed in a thin surface layer less than one μm thick while the semiconductor substrate is typically 700 μm to 750 μm thick. In FIG. 2A, the semiconductor substrate 202 is selectively oxidized, using methods well-known in the art, to form a field isolation region 204 composed of silicon oxide, which bounds an active area or well region 206 in which the integrated transistor device is to be formed. The size of the active area of semiconductor substrate 202 depends on the application, but can be as small as one micron or less. The field isolation region 204 serves to electrically isolate the integrated device from outside electromagnetic disturbances. Although field isolation region 204 is represented by a particular shape in the figures, it should be understood that this is merely an illustrative representation. The actual configuration may be quite different with, for example, more rounded features that extend deeper into the semiconductor substrate than shown in FIG. 2.

If the device to be formed is a p-channel device, n-type dopants such as arsenic (As), phosphorus (P), antimony (Sb), or other donor atom species, are introduced into the semiconductor substrate 202 to form well region 206. Conversely, if the integrated device is to be a n-channel device, p-type dopants such as boron (B), aluminum (Al), gallium (Ga), indium (In) or other acceptor atom species, are introduced into the semiconductor substrate 202 to form the well region 206. The depth to which well region 206 is formed depends upon the scaling of the integrated device and, with present technologies, is generally on the order of hundreds of nanometers for integration densities of one micron or less. The dopants introduced to form well region 206 can be implanted or diffused, for example, into the semiconductor substrate 202 using one of a wide variety of well known techniques such as ion implantation or plasma immersion doping.

Following introduction of the dopants into the well region, semiconductor substrate 202 is annealed using conventional methods to restore semiconductor substrate crystallinity and electrically activate the implanted dopants. Conventional thermal annealing is an acceptable option at this stage because the formation of well region 206 requires less control over dopant diffusion as compared to SDE formation. In one embodiment, thermal annealing is performed by heating the semiconductor substrate to between about 800° and 1100° Celsius for about five minutes using well-known techniques. Substrate 202 can also be annealed by exposure to radiant energy generated by a laser or flash-lamp, for example, at wavelengths at which the semiconductor substrate is absorptive.

In FIG. 2A, a gate insulator layer 208 is formed on semiconductor substrate 202. Gate insulator layer 208 illustratively is composed of substances such as silicon oxide (SiO₂), silicon nitride (Si₃N₄), aluminum oxide (Al₂O₃), titanium oxide (TiO₂), or barium strontium titanium oxide (BaSrTiO₃). Gate insulator layer 208 is formed with any of a variety of thermal oxidation or deposition techniques, including remote plasma oxidation (RPO) and chemical vapor deposition (CVD), using commercially-available equipment. The thickness of the gate insulator layer 208 depends upon the scaling of the integrated device and is generally one to hundreds of nanometers in thickness.

In FIG. 2B, a gate conductor layer 210 is formed over the gate insulator layer 208. Gate conductor layer 210 is formed of a semiconductor, metal or alloy that is electrically conductive. In addition, gate conductor layer 210 preferably has a relatively high melting point to enhance the process window available for performance of the invented method. Gate conductor layer 210 illustratively is composed of polysilicon, tungsten (W), titanium nitride (TiN) or their alloys. Gate conductor layer 210 can be formed by well-known techniques, such as chemical vapor deposition (CVD) or plasma-enhanced CVD (PECVD). Also shown in FIG. 2B is a dielectric antireflection coating (DARC) layer 211, typically SiOₓN_{y}, which is deposited by conventional chemical vapor deposition techniques. A photoresist layer 212 is formed over the DARC layer 211. In one embodiment, photoresist layer 212 is formed by spin-coating.

In FIG. 2C, gate insulator layer 208 and gate conductor layer 210 are patterned to define where features, such as gate region 220, will be positioned once the fabrication process is complete. As used herein, gate region 220 collectively refers to gate insulator layer 208 and gate conductor layer 210 overlying the channel region 235 of the integrated device. To define features such as gate region 220, resist layer 212 is shielded with a mask (not shown) having an image and then developed by exposing the shielded resist layer 212 to radiant energy or chemical developers. The purpose of the DARC coating 211 is to enhance the resolution performance of the image forming process. Thus, selective portions of resist layer 212 are exposed, in either a positive or negative sense as appropriate for the particular substance composing the resist layer, in accordance with the pattern in the mask image. In an alternative embodiment, an ion beam is used for selective exposure of resist layer 212. A final stage in the development process comprises rinsing the substrate with a rinse chemical to wash away portions of resist layer 212 that were not shielded by the mask. For representative developer substances and methods, see Microchip Fabrication, id., pp. 243-250.

As a result of the development process, resist layer 212 is patterned in accordance with a mask image. Patterned resist layer 212 is then hard baked using well known methods in the art in order to harden layer 212 and achieve good adhesion between resist 212 and DARC layer 211. As a result of the hard bake, layer 212 is resistant to etching.

The portions of gate insulator layer 208 and gate conductor layer 210 not protected by resist layer 212 and DARC layer 211 are removed by etching with an etchant substance and/or process such as plasma etching, ion beam etching, or reactive ion etching (RIE) in order to form features such as gate region 220 or region 221. Exemplary etching methods are found in Microchip Fabrication, id., pp. 256-270. In an alternative embodiment, rather than forming gate region 220 by selective etching, the gate is formed by selective deposition by depositing the gate insulator 208 and gate conductor layer 210 over a limited portion of semiconductor substrate 202 overlying channel region 235 (FIG. 2D).

In FIG. 2D, ions 230 are implanted into semiconductor substrate 202 to amorphize localized portions of the semiconductor substrate, or more specifically, well region 206, as part of the process of forming source region 224 and drain region 226 for the integrated transistor device. The amorphization step destroys the crystallinity of source and drain regions 224, 226, thereby lowering their melting temperatures well below those of the crystalline semiconductor substrate 202, field isolation region 204, and gate region 220. In one embodiment, the amorphized source and drain regions 210, 212 are formed to a depth on the order of 15 nanometers to 50 nanometers. The ion species, the implantation energy and the dosage are selected to produce amorphized regions having a desired depth.

A number of ion species can be used to produce implanted regions 224, 226. For example, the ions can be silicon, argon, arsenic, or germanium. Silicon, argon and germanium are neither donors nor acceptors and thus have no impact on the concentration of electrically active impurities in the source and drain regions 224, 226. Conversely, if a donor such as arsenic or an acceptor atom species is used as the amorphization implant, the dosage thereof should be included as part of the total dosage used to form the SDE regions 224, 226. Following a preamorphization implant, the desired dopant 231 is implanted to a depth not exceeding a preamorphized depth. If the integrated device is a p-channel device, the implanted dopants are p-type, and conversely, if the device is a n-channel device, the implanted dopant ions 231 are n-type. The ion implantation step can be performed with a variety of commercially-available equipment, including the Quantum Ion Implanter™ from Applied Materials, Inc. of San Clara, Calif.

In another embodiment, dopants 231 are introduced into the source drain regions to the desired depth by plasma doping. In this case, a separate amorphization step is not necessarily required. The depth of penetration for these species (e.g., BF₂) is limited by the plasma parameters and results in the shallow implant depth required for modern IC fabrication.

In FIG. 2E, an insulator layer 232 is formed over gate region 220 and source and drain regions 224, 226. The insulator layer 232 can be composed of silicon oxide, silicon nitride or other substances, as is well-known in the industry. Insulator layer 232 can be formed to a thickness of thousands of nanometers or more, for example, through such well-known techniques, such as plasma-enhanced CVD (PECVD), using well-known, commercially-available equipment. The insulator layer 232 is used to isolate the surface of the device from chemical reaction with trace ambient gases during the laser annealing process. Layer 232 can also be used to alter the relative optical reflectivity of the different regions in order to improve the performance of the implant anneal.

The laser annealing event that is optimized by the methods of the instant invention is shown in FIG. 2F. Here, the surface of the semiconductor substrate is exposed to a pulse of laser radiation 280 at an appropriate wavelength, pulse length, pulse shape, and energy density. The maximum exposed area is determined by the required energy density for the pulsed laser annealing and the total available pulse energy of the laser. Annealing protocols that do not deform gate regions 220 or melt crystalline well region 206 are desirable. In this laser annealing step it is undesirable for the melt depth in the source drain extension regions to extend beyond the amorphous depth defined by the amorphization implant step. Deeper melt depths facilitate the diffusion of dopant from the doped amorphous layers into the undoped molten layers. Such undesirable diffusion would sharply and deleteriously alter the electrical characteristics of the circuits on the semiconductor substrate. Conventional methods are used to complete the interconnection of the device.

It will be appreciated that the methods of the present invention may be used to crystallize and/or activate regions 224 and 226 in FIG. 2 when they have been implanted with dopants, irrespective of whether regions 224 and 226 are amorphous. Accordingly, the methods of the instant invention are applicable to activating any implanted region on a patterned semiconductor device and are not limited to the case where the implanted regions are amorphized.

II. Description of the Modeling Method

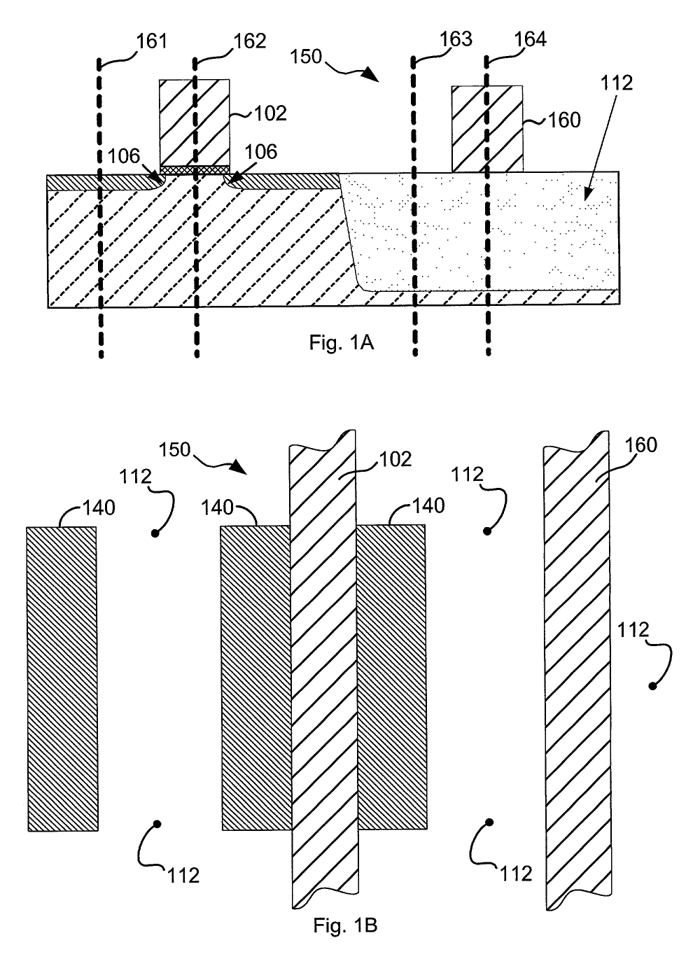

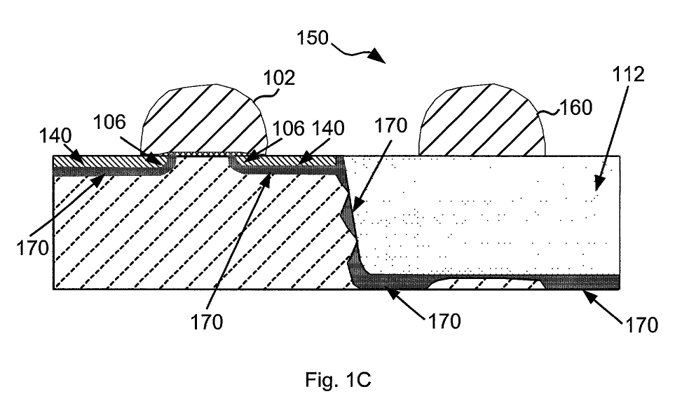

Laser systems suitable for implant anneal applications are expensive in capital and experimental effort. A given system is capable of providing results only within a narrow range of pulse length/wavelength combinations. Many different systems would be required to explore the parameter space of interest on a trial and error basis. The goal of the mathematical modeling approach is to explore the laser parameter space with sufficient accuracy to significantly reduce the field of candidate laser systems appropriate for the target process. The modeling method is illustrated for the particular case of source drain extension implant anneal at the gate level during silicon CMOS integrated circuit fabrication. The method is more generally applied to the problem of establishing pulsed laser annealing parameters for any target process while limiting the maximum temperature of collateral structures, such as gate 102, shallow trench isolation (STI) 112, and polysilcon over STI 160 (FIG. 1A).

In the modeling approaches of the instant invention, each structure on the patterned substrate that has been subjected to implant anneal is viewed as a stack of layers. Therefore, the structures on the substrate, such as gate 102, shallow trench isolation (STI) 112, and polysilcon over STI 160 (FIG. 1A), are each referred to as a stacked structure. The thermal response of stacked structures is sensitive to the details of the composition and geometry of the pattern on the substrate. For a particular patterned substrate, the instant invention advantageously models all unique layer structures in the substrate. Accordingly, one embodiment of the present invention provides a method for modeling an annealing protocol for an implant anneal of a patterned semiconductor substrate. In the method, a plurality of vertically unique one-dimensional layer structures are modeled including a one-dimensional target layer structure and at least one one-dimensional ancillary layer structure. For example, in FIG. 1A, the source drain extension region 140 is the target structure. A one-dimensional target layer structure that describes this target structure consists of a 20 nm of preamorphized silicon layer on a silicon substrate layer. This one-dimensional target layer structure is illustrated in FIG. 1A as element 161. The ancillary structures existing in patterned semiconductor substrate of FIG. 1A are gate 102, STI 112, and Poly/STI 160. Each of these ancillary structures is defined as a one-dimensional ancillary layer structure. An example of this modeling process for a particular patterned substrate is illustrative of the technique. In this example, gate 102 (one-dimensional ancillary layer structure 162 in FIG. 1A), is defined as 120 nm polySi/5 nm SiO₂/Si (001) @ Nd=1E¹⁸ cm⁻³. STI 112 (one-dimensional ancillary layer structure 163 in FIG. 1A) is defined as 292 nm SiO₂/Si (001) @ Nd=1E¹⁶ cm⁻³. Finally, Poly/STI 160 (one-dimensional ancillary layer structure 164 in FIG. 1A) is defined as 120 nm polySi/292 nm SiO₂/Si (001) @ 1E¹⁶ cm⁻³. Specification of these four one-dimensional layer structures describes all the relevant features of the substrate surface shown in FIG. 1A.

After the one-dimensional target layer structures for a given patterned substrate of interest have been defined, the relevant optical and thermal parameters for each sublayer in the vertically unique one-dimensional layers are determined. These parameters are used as inputs to modeling software such as LIMP.

The required optical parameters include the complex index of refraction, n=n+ik. For modeling approaches in accordance with the instant invention, the complex index of refraction is specified for each phase (solid and liquid) of each material at all temperatures (300K<T<Tm, where Tm is the melting temperature in K), at all wavelengths of interest. For the example provided above, the materials of interest are,

1) crystalline silicon, cSi, at a doping density of 1E¹⁸ impurities/cm³,

2) crystalline silicon, cSi, at a doping density of 1E¹⁶ impurities/cm³,

3) polycrystalline silicon, pSi,

4) amorphous silicon, aSi,

5) liquid silicon, LSi,

6) silicon dioxide, SiO₂.

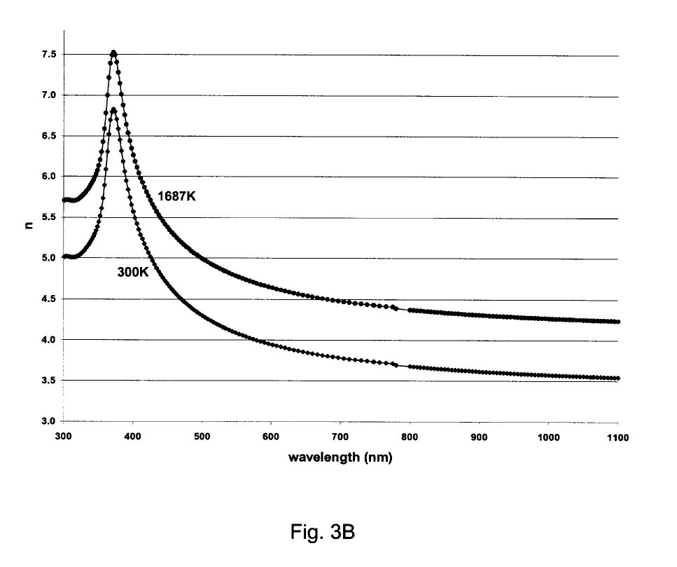

Examples of the wavelength and temperature dependence of the imaginary and real parts of the complex index of refraction for bulk crystalline silicon for doping levels less than 1E¹⁷ cm⁻³ are given in FIGS. 3A and 3B. Similar plots are used for all phases of each material in the patterned semiconductor substrate of interest.

The two relevant optical parameters for input to modeling software such as LIMP are the absorption coefficient and stack reflectivity. The absorption coefficient, α, is calculated from the imaginary part of the index of refraction using,

α(λ,T)=4πk(λ,T)/λ,

where λ is the wavelength, k is the complex part of the index (extinction coefficient) and T is the temperature in Kelvin. A common form for the temperature dependence of the absorption coefficient is provided by Jellison (Semiconductors and Semimetals, v23, R. Wood, C. White, and R. Young, eds., Academic Press, 1984, Ch3),

α(λ,T)=A(λ)exp(T/T₀),

where A and T₀ are parameters associated with specific experimental data.

The reflectivity of the stack structures is calculated from a matrix method using the real and imaginary parts of the complex index for each layer in the stack and its thickness in accordance with known methods in the art. Here, a software package entitled Thin Film Optical Calculator (TFOC) is used to calculate the normal incidence reflectivity polarization independent) for each of the four one-dimensional layer structures defined in the example above as a function of wavelength and temperature. Commercial software packages are commonly available to perform this task. Representative values for the reflectivity of the stack structures calculated from TFOC at 748 nm and 300K are provided in Table I.

TABLE I
Layer definitions and calculated reflectivities for reduced
one-dimensional structures pertinent to SDE implant annealing
by PLA calculated at 748 nm and 300K.

| | | | | REFLECTIVITY |
|---|---|---|---|---|
| STACK | | STACK | | @ |
| DESCRIPTION | MNEMONIC | STRUCTURE | | 748 NM/300K |
| Crystalline silicon | Csi | bulk | | 0.344 |
| Amorphous silicon | SDE | 20 | nm | 0.440 |
| Crystalline silicon | | bulk | | |
| DARC | Gate | 30 | nm | 0.286 |
| Poly slicon | | 120 | nm | |
| SiO₂ | | 5 | nm | |
| Crystalline silicon | | bulk | | |
| SiO₂ | STI | 292 | nm | 0.204 |
| Crystalline Si | | bulk | | |
| Poly silicon | PolySTI | 120 | nm | 0.164 |
| SiO₂ | | 292 | nm | |

| | |
|---|---|
| Crystalline silicon | bulk |

The temperature dependence of the normal incidence reflectivity, R, of bulk silicon is given by,

R(λ,T)=R₀(λ,300K)+m(T−300K),

where R₀ is the room temperature reflectivity and m=5×10⁻⁵K⁻¹. This relation is generally valid for bulk semiconductors below the optical bandgap. This form can also be used for the temperature dependence of multi-layer stacks by choosing appropriate values of m.

In addition to the optical properties, the thermal properties of the individual vertically unique one-dimensional layer structures are required. Specifically, the properties of interest are,

1) thermal conductivity, K (W/cm-K),

2) volume heat capacity, ρCₚ (J/cm³/K),

3) melting temperature, Tₘ (K),

4) latent heat of melting/solidification, H (J/cm³),

5) volume expansion upon melting, ΔV (%).

The thermal conductivity and heat capacity are temperature dependent quantities but are not a function of the laser wavelength. Values for the materials of interest are commonly tabulated in the literature. However, the thermal properties of amorphous silicon and silicon dioxide are sensitive to their preparation. Care in selecting temperature dependent values appropriate to the actual target materials is required for accurate modeling. Representative values used in this work for amorphous silicon prepared by ion implantation are given in Table II.

TABLE II
Thermal parameters for amorphous silicon used. The amorphization
implant species is ⁷²Ge at a dose of 1E¹⁵ cm⁻². An implant energy
of 10 keV produces an amorphization depth near 20 nm.

| PROPERTY | VALUE (UNITS) | |
|---|---|---|
| Thermal conductivity | 0.0245 | W/cm/K @ 300K |
| | 0.0498 | W/cm/K @ 1500K |
| Heat Capacity | 1.609 | J/cm3/K @ 273K |
| | 2.367 | J/cm3/K @ 1500K |
| Melting temperature | 1423K | |
| Latent heat | 2986 | J/cm³ |

| | |
|---|---|
| Volume expansion coefficient | 100% |

Because optical and thermal properties differ between liquids and solid phases, it is also necessary to determine which sublayers in a stack are liquid during the anneal. In order to accurately model the dynamics of melt front propagation in the modeling experiments, a velocity undercooling constant is required for any material that is allowed to melt during a simulation. The velocity of the melt front, v, is assumed proportional to the deviation of the solid-liquid interface temperature (Tᵢ) from the equilibrium melting temperature (Tₘ) for the material,

v=μ(Tᵢ−Tₘ).

The velocity undercooling constant, μ, is generally not available for the temperatures of interest. An estimate is made based on Turnbull's theory of collision limited solidification,

μ=v₀H/R Tₘ²,

where v₀ is the speed of sound, H is the latent heat of the phase change, and R is the universal gas constant. For the current source drain extension anneal case, a value of 0.0667 (m/s)/K is estimated. A software package, such as LIMP, then models the propagation of the melt front during melting or resolidification in terms of the deviation of the interface temperature from the equilibrium melting temperature. The solid or liquid phases of the material are allowed to superheat and supercool.

A software package such as LIMP models the absorption of optical energy using Beer's Law,

I(z)=I₀(x,y,t) {1−R(x,y)}exp{−α(x,y,z)z},

where I(z) is the light intensity at depth z, I₀ is the incident light intensity at the substrate surface, x,y are spatial coordinates in the plane of the substrate, z is the spatial coordinate into the substrate, R is the surface reflectivity, and α is the absorption coefficient. As indicated above, R and α are also temperature dependent. Here, the intensity of the incoming radiation is assumed uniform over the area of the illuminated spot,

I₀(x,y,t)=I₀(t),

where I₀ is the intensity at the plane of the target. I₀(t), then, is just the temporal pulse shape of the laser when the beam is homogenous over the area of the beam. The importance of the reflectivity and the absorption coefficient become apparent since they totally describe the intensity that is not reflected at the surface and the propagation of absorbed radiation into the structure. The absorption coefficient, α(x,y,z) is a function of all the spatial coordinates and adequately describes the case of different materials adjacent on the surface, i.e., the x and y dependence, and the case of stacked structures, i.e., the z dependence.

The photon energy is absorbed by the electron distribution in the material. Heat is generated by the interaction of excited electrons with the crystal. The assumption is made that the time scale of the absorption/relaxation process occurs on time scales much shorter than the duration of the pulse. For modeling purposes, the conversion of laser energy to heat energy is assumed to be instantaneous. The details of the interaction are ignored. This assumption constrains the temporal pulse shape such that a minimum pulse duration can be accurately modeled (on the order of 100-1000 fS). Further, the pulse shape must be free of “spikes” having characteristic widths on this time scale.

The conduction of heat into the material is modeled using the Fourier heat flow equation,

Q=−κ grad T(z)

where,

Q is the energy flow across a unit area,

k is the thermal conductivity,

and grad T(z) is the temperature gradient.

The simulation is carried out only in the depth direction, i.e., a one-dimensional heat flow across lamellae parallel to the substrate surface. The heat capacity is relevant to the calculation of the temperature distribution. The thermal diffusion length, L_{T}, is an important thermal characteristic of the multi-layer stack,

L_{T}=sqrt (κΔt/ρCₚ),

where κ is the thermal conductivity, Δt is a time interval, and ρCp is the volume heat capacity. L_{T} is a measure of the distance over which the temperature distribution falls to 1/e of its original value over a relevant time scale if Δt=full width half maximum (FWHM) of the pulse shape.

The critical capability of the modeling approach is now evident. By coupling the solution for the time evolution of the temperature profile with Beer's Law and the Fourier heat equation, a software package, such as LIMP, explores the laser anneal protocol parameter space in terms of the ratio of the effective absorption length to the effective thermal diffusion length. Details on this coupling are found in the LIMP Version 3.62 User's Guide, July 1998, by Patrick Smith and David Hoglund. The absorption length for crystalline silicon, for example, increases as the wavelength increases and the thermal diffusion length decreases as the pulse width decreases. One expects that the relative rates of heat absorption and dissipation for different structures determine the relative temperature profiles. Favorable situations are engineered by judicious selection of the wavelength, pulse length, and pulse shape at the energy density required to accomplish the target process. Since stacked structures are not amenable to an analytical solution for “effective” values for absorption coefficient and thermal diffusion length, a finite element analysis approach numerically approximates the relevant behavior.

The numerical modeling results report the time evolution of the temperature profiles for the input structure. The dynamics of phase changes are described by tracking the solid/liquid interface temperature and invoking the velocity undercooling constant to determine the velocity of the interface. For energy densities high enough to cause surface melting, there will be a time during resolidification where the interface temperature will have a maximum deviation from the equilibrium melt temperature. The velocity of the melt-solid interface will be at a maximum at that time.

Prior experimental results have determined that, e.g., for (001) silicon, if the regrowth velocity, Vrg, is greater than 10 meters per second (m/S), the resolidified silicon contains defects. Hence, an optimum pulse laser annealing protocol for source drain extension anneal is constrained by the maximum allowable regrowth velocity. If Vrg is greater than 10 m/S, the regrowth is not sufficiently crystalline and the protocol fails to accomplish the desired result, i.i., the desired source drain extension anneal.

The numerical analysis provides an estimate of Vrg and is used as a decision criterion for acceptance of a parameter set for implant anneal in the instant invention. The constraint on Vrg sets a lower bound on the pulse length since the thermal diffusion length is short and steep temperature gradients then occur in one or more structures.

The mathematical model of the instant invention seeks to quantify the important interplay between the effective optical absorption length and the effective thermal diffusion length for complicated stacks of materials. In summary, a successful candidate protocol in accordance with the instant invention must demonstrate the following three criteria by simulation:

1) the target implant region on a patterned semiconductor substrate, e.g., a source drain extension region, is fully melted to a desired depth,

2) the maximum temperature in all other features on the patterned semiconductor substrate is less than the local melting temperature (Tₘₐₓ<Tₘ) at all depths and at all times, and,

3) Vrg is less than about 10 meters per second.

A large parameter space for success exists. In order to determine the boundaries of the successful protocols, the explicit goals of the modeling exercise of the instant invention are:

1) determine the maximum pulse length at any λ for the starting structure, and

2) determine a minimum possible wavelength for the target process.

An element of the modeling approach taken in the instant invention is that the full three-dimensional pattern of the semiconductor substrate is reduced to a finite set of one-dimensional material stacks for modeling. It is appreciated that heat flow parallel to the substrate surface will occur across the vertical interfaces of the real three-dimensional pattern. This two-dimensional heat flow can be modeled separately with commercially available software, but is rejected in the current invention since it obscures the effects of absorption versus diffusion length.

In the one-dimensional analysis, the effects of two-dimensional heat flow can be minimized by choosing a protocol that minimizes lateral temperature gradients during the anneal and is determined by comparing the temperature profiles of the individual one-dimensional structures.

In one aspect of the instant invention, a one-dimensional analyses is executed as follows:

1) choose a wavelength range from available laser technology (e.g., 197 nm<λ<10.6 μm).

2) choose a trial λ,

3) choose a temporal pulse shape that is gaussian,

4) choose a full width at half maximum for temporal pulse (pulse length),

5) calculate the required Ea (energy density for full anneal) for the one-dimensional target structure (e.g. 161 FIG. 1A),

6) calculate T(z,t) for each ancillary one-dimensional structure (e.g. 162, 163, and 164 of FIG. 1A) at E=Ea,

7) identify the maximum T(z,t), where maximum T(z,t) is defined as “Tₘₐₓ,” in each ancillary one-dimensional structure,

8) compare Tₘₐₓ to the melting temperature Tₘ of each of the sublayers:

(i) if Tₘₐₓ=Tₘ for only one sublayer in all ancillary structures and Tₘₐₓ<Tₘ for all others and Vrg is less than about 10 m/S, then, the maximum pulse length is found for this λ,

(ii) if Tₘₐₓ=Tₘ for only one sublayer in all ancillary structure and Tₘₐₓ<Tₘ for all others and Vrg greater than about 10 meters per second, then, no positive process window exists for this wavelength.

(iii) if Tₘₐₓ>Tₘ for any structure, decrease the pulse length and go to step 5), and

(iv) if Tₘₐₓ<Tₘ for all structures, increase the pulse length and go to step 5).

The endpoint of a modeling iteration in accordance with one embodiment of the present invention is a plot of the calculated maximum pulse length at any wavelength to the desired granularity. The plot determines the boundaries in the wavelength/pulse length process space where the PLA protocol has zero process window. The required energy density for full anneal is calculated in the analysis as a matter of course. The result is generated for a single pulse shape. Also, the minimum candidate wavelength is determined based on the constraint that Vrg is less than about 10 m/S.

In some embodiments of the present invention, additional modeling is performed to determine the effect of pulse shape on the process window of a laser annealing protocol identified through modeling. The method provided above assumes a gaussian pulse shape of the form,

I₀(t)=Aexp(−t²/τ²),

where A is a scaling constant and τ is proportional to the pulse full width half maximum. It has been determined, using the techniques of the instant invention, that for the source drain extension implant anneal example, the process window is increased (or, equivalently, the maximum usable pulse length is increased) if the pulse shape is more nearly rectangular.

Other possible trials include right triangle, left triangle, and isosceles pulse shapes. All other possibilities are subsets of these. Pulse trials must be free of temporal spikes. A particular pulse shape is deemed superior to another if the process window is improved or the required energy density is reduced.

The maximum pulse length is ultimately determined by the requirement that the implant anneal be accomplished within 50 mS to avoid transient enhanced diffusion of, dopants. Of particular concern is diffusion of boron in silicon. A smaller pulse length limit can be determined approximately from maximum pulse energy available from real laser systems. As the pulse length increases beyond, e.g., 50 nanoseconds, the peak pulse power required to process the implant region dictates that the total pulse energy becomes on the order of hundreds of joules per pulse (λ dependent), which is impossibly large. In addition, when the pulse length exceeds a few milliseconds, the thermal diffusion length approaches the substrate thickness for crystalline silicon. The advantage of rapid cooling of the source drain extension available in pulsed laser annealing is then lost to the slow thermal response of a large substrate mass.

The estimated maximum pulse length, then, is determined from maximum pulse energy specifications for real lasers. The maximum pulse length is estimated to be near 50 nanoseconds for a 200W-500W laser operating at a pulse repetition rate of 10 Hz.

Modeling Results.

### EXAMPLE 1

748 nm /Vary Pulse Length

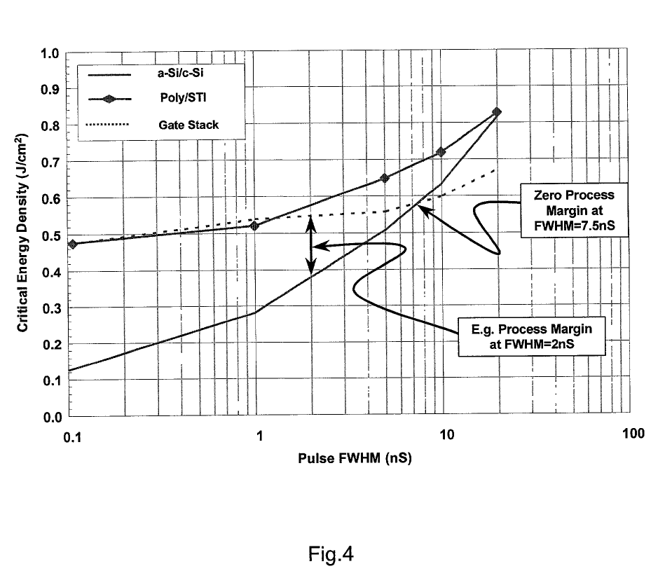

An example of a modeling result in accordance with the instant invention is shown in FIG. 4. Here, the laser wavelength is 748 nm and the pulse shape is gaussian. Typical material properties are chosen, except for the absorption coefficient of crystalline silicon. Here, the absorption coefficient for crystalline silicon is taken as,

α(cSi)=535exp(T/285)cm⁻¹.

This absorption coefficient is chosen to explore the high α case at 748 nm. The details of the reduced one-dimensional structures (20 nm amorphous silicon, gate, polysilicon on shallow trench isolation, and shallow trench isolation) are such that the gate structure is the stack that limits the energy density of the laser annealing protocol. From FIG. 4, one determines that the minimum pulse length for a zero process window is near 7.5 nano seconds. At this pulse length, the energy density required for full anneal of the source drain extension region (0.57 J/cm²) brings the surface of the gate stack structure nearly to the melting temperature of the polysilicon used for the gate. Longer pulse lengths require an additional pulse energy for full source drain extension anneal and cause a shallow melt in the gate structure.

FIG. 4 indicates that, for the assumed structure and material properties of the patterned semiconductor substrate, the minimum pulse length that fully anneals a 20 nm amorphous silicon implant without destroying the adjacent gate structure is 7.5 nS. Therefore, the data point 7.5 nS at 748 nm is plotted on a pulse length vs wavelength plot. Then, in accordance with the present invention, the modeling is continued at a new wavelength to complete a zero margin protocol plot.

### EXAMPLE 2

748 nm/Vary Crystalline Silicon Absorption

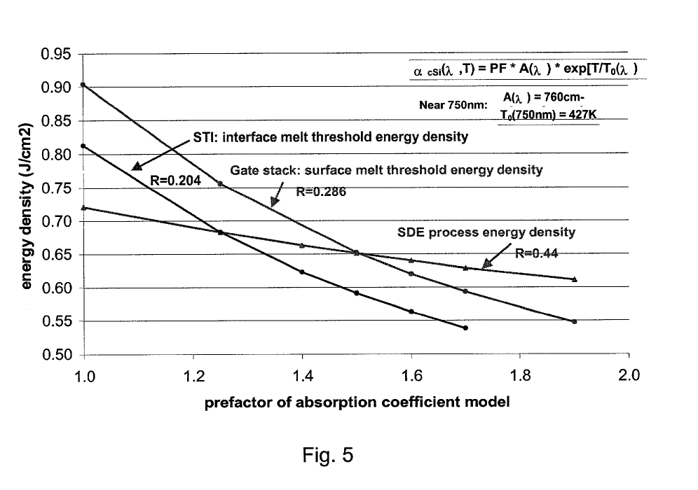

The estimated value of selected parameters is critical to the model predictions. Results of a modeling effort to determine the dependence of the process window as a function of the absorption coefficient for crystalline silicon is shown in FIG. 5. Here, a series of calculations for the process window are made while varying the estimation for α(cSi) according to,

α(cSi)=PF*760exp(T/427),

where the PF=1 case corresponds to the low light intensity approximation.

The one-dimensional structure parameters for this example are chosen such that the shallow trench isolation regions are the limiting structures. The limiting stack has changed from the previous example by simply assuming a different depth of trench oxide that reduces the reflectivity (as calculated from TFOC) from 0.370 in example 1 to 0.204. From the modeling results shown in FIG. 5, it is determined that a zero process window exists at 748 nm and FWHM=20 nS for a near rectangular pulse if the high intensity absorption coefficient for crystalline silicon does not exceed 1.2× its low light intensity value.

III. Experimental Verification Procedure

The experimental examples provided above indicate that the process of modeling the effects of a laser annealing protocol on a patterned semiconductor substrate is sensitive to the details of structural and material properties parameters. In one embodiment of the present invention, the predictive accuracy of the modeling results are improved by comparing model results to measurements of physical experiments that do not require full laser system development. In this aspect of the invention, model parameters are improved by performing simple experiments at an attractive wavelength, the properties estimates improved, and the results extrapolated to different pulsed laser annealing parameters by calculation.

The most important parameter at a given wavelength and pulse length is the energy density required to fully process an implanted region of semiconductor. To verify that the energy density required to fully process an implanted region of a semiconductor has been correctly computed, various physical experiments are performed. These physical experiments include cross sectional transmission electron microscopy (XTEM) analysis to verify crystalline regrowth, secondary ion mass spectoscopy (SIMS) analysis to determine the impurity profile, and sheet resistance (Rs) measurements to establish activation of implanted dopants.

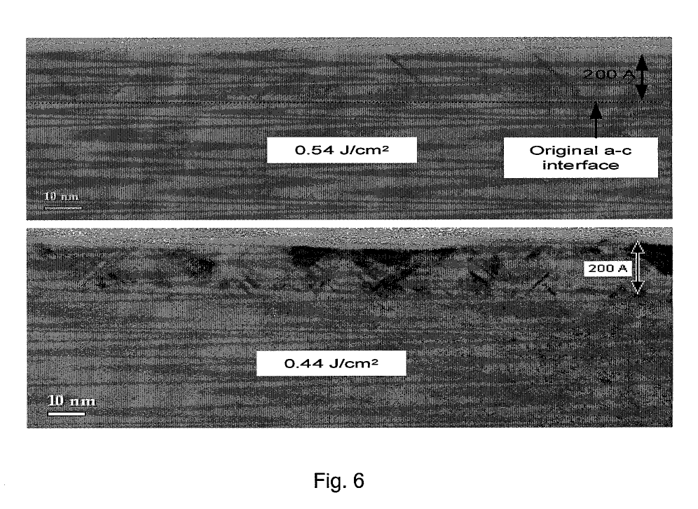

XTEM micrographs of a pulse laser annealing implant for a 532 nm, 18 nS FWHM, near gaussian laser pulse are shown in FIG. 6. Inspection of the micrograph at a depth near 20 nm indicates that an energy density of 0.54J/cm² is required to fully recrystallize the amorphous region.

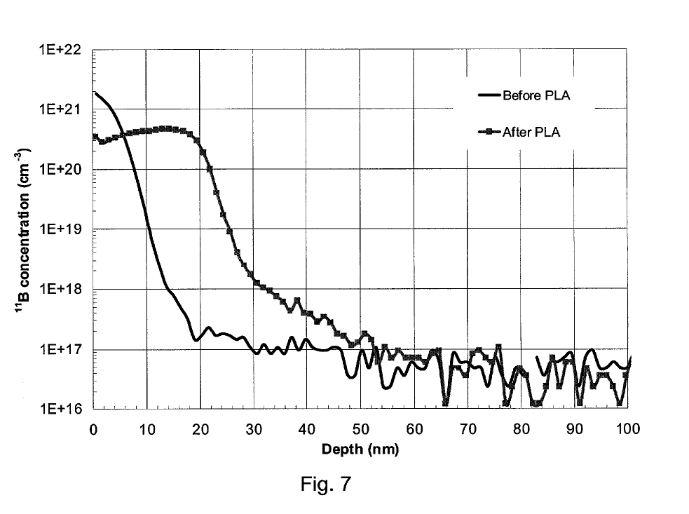

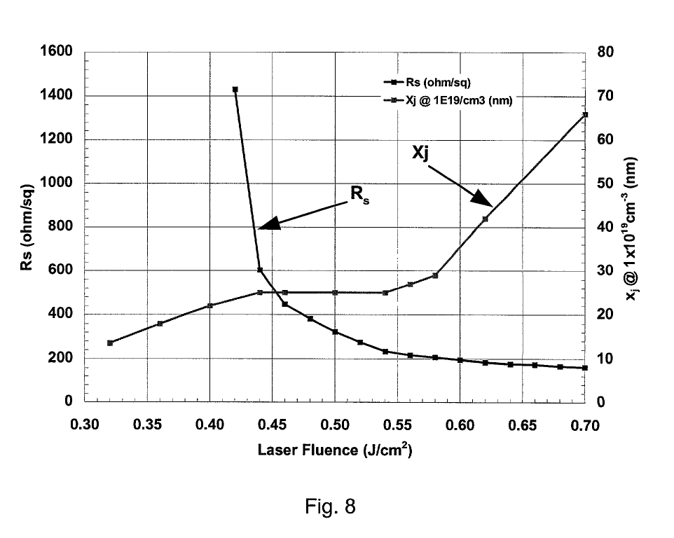

SIMS profiles of the boron impurity concentration before and after pulsed laser annealing are shown in FIG. 7. For the energy density of 0.54J/cm², the boron concentration is shown to be uniform within the top 20 nm of the substrate and falls abruptly thereafter. An estimate of the pn junction depth, xⱼ, is taken from the data at the point where the concentration falls to 0.5× the uniform value. A plot of xj versus energy density can be generated by SIMS profiles measured at different incident energy densities. The results of such an experiment are shown in FIG. 8.

Also plotted in FIG. 8 is the sheet resistance of the recrystallized amorphous region as a function of energy density. Analysis of the SIMS and Rs data provides a measure of the activation of implanted impurities. The SIMS profile reports the chemical concentration of boron in the surface region and the Rs data reports the electrically activated concentration (integrated over the depth of the impurity distribution).

Taken together, the results summarized in FIGS. 6-8 provide verification that pulsed laser annealing is effective at recrystallizing implanted regions of crystalline silicon and activating the impurities. For the particular example of a 532 nm/18 nS gaussian pulse, the required energy density is 0.54J/cm². In accordance with the present invention, the model parameters for full source drain extension anneal is refined based on the results of physical experiments such as those summarized in FIGS. 6-8. In particular, the estimates for the thermal conductivity of the amorphous silicon layer and the variation of stack reflectivity for a liquid silicon/amorphous silicon/crystalline silicon stack are refined to bring the model prediction into agreement with the physical result. It will be appreciated that a liquid silicon/amorphous silicon/crystalline silicon stack occurs when the one-dimensional target layer structure is subjected to a laser annealing protocol with a suitable energy density during a modeling experiment. The refinement of these parameters yields improved modeling results.

A common material to all one-dimensional stacks is the bulk silicon substrate. The results of the modeling shown in FIG. 5 demonstrate the important role of the estimated absorption coefficient of this material to the eventual model result. The thermal properties of crystalline silicon have been extensively reported and the literature values are consistent. The optical absorption at high light intensity during pulse laser annealing, however, is relatively unknown. The relevant high intensity absorption coefficient model for crystalline silicon can be determined from a simple measurement of the melt threshold energy density at a chosen wavelength using low energy pulsed lasers.

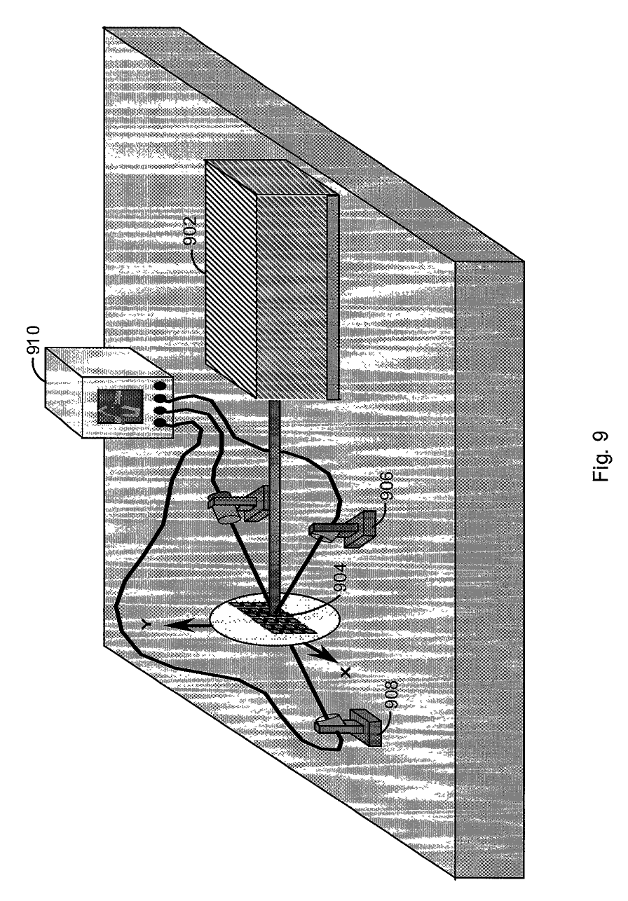

Melt thresholds are measured in pulsed laser annealing experiments by making time resolved reflectivity (TRR) and transmission (TRT) measurements. The experimental arrangement for TRR and TRT experiments is shown in FIG. 9. The reflectivity measurement uses the physical observation that the reflectivity of LSi is twice the reflectivity of cSi (crystalline silicon). A probe laser 902 is focussed onto the same area of the wafer 904 as the laser used for pulsed laser annealing. During the pulsed laser annealing pulse, the detector output 906 monitors the reflectivity of the surface. The detector will report a higher incident intensity for energy densities that cause surface melting. The threshold energy density for any structure can be obtained using this technique.

A complementary measurement is made by monitoring the transmitted radiation using detector 908 if the probe laser is chosen to have a wavelength where the crystalline silicon is transparent (e.g., 1.5 μm). During the formation of a surface melt, the transmission will drop abruptly to zero since the liquid silicon layer, which is a liquid metal, will absorb the entirety of the energy of the incident pulse. TRT also provides absorption coefficient information for long lived optically generated carriers.

Using either TRR or TRT, the threshold energy density of crystalline silicon can be determined for any wavelength, pulse length, or pulse shape protocol. From the energy density measurement, the high intensity absorption coefficient of crystalline silicon as a function of temperature can be uniquely determined at the chosen wavelength.

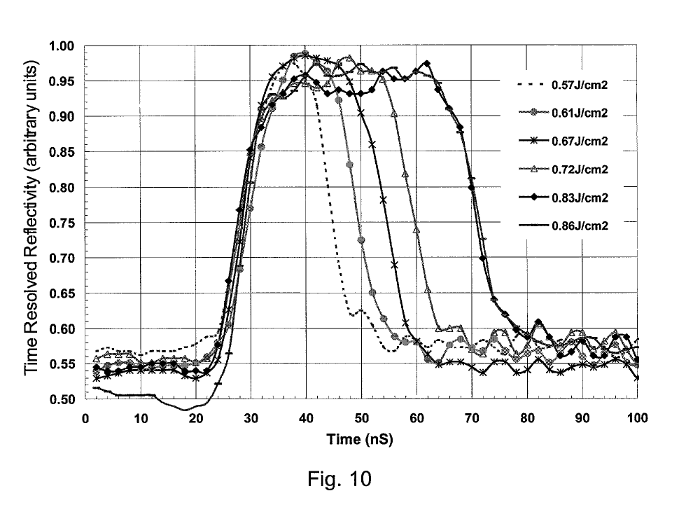

The TRR and TRT techniques are especially useful as process monitors since they report the surface melt duration of a structure. Representative TRR signals from an amorphized silcon substrate irradiated with near rectangular, 20 nS pulses at 748 nm at different energy densities are shown in FIG. 10. The probe laser is a continuous wave 1.5 μm InGaAs laser diode. As the energy density is increased, the duration of the TRR pulse increases, indicating that the surface is molten for longer times as the melt front penetrates into the substrate, reaches a maximum depth, and returns to the surface. The target energy density for source drain extension anneal is determined from XTEM, SIMS, and Rs measurements as described above and corresponds uniquely to one of the TRR traces shown in FIG. 10. In this case, the XTEM/SIMS/Rs data indicate that the target energy is near 0.61J/cm². The TRR trace corresponding to 0.61J/cm² indicates a surface melt duration near 15 nS.

In one aspect of the present invention, the melt duration at the optimum energy density for source drain extension anneal is advantageously used to refine the estimate for the velocity undercooling constant for amorphous silicon. Further, the target energy density is conveniently established by adjusting the incident pulse energy at this wavelength and pulse length to produce the TRR signal indicating 15 nS melt duration.

Experimental Measurement of Ancillary Structure Critical Energies

The one-dimensional modeling drill of the instant invention predicts the threshold energy densities for surface or interface melting of patterns existing on the associated three dimensional patterned semiconductor substrate. In one aspect of the instant invention, the modeling results are verified experimentally by fabricating the one-dimensional structures on appropriate substrates and performing TRR and/or TRT measurements at the target energy density for the SDE anneal. The presence/absence of a melt signal in TRR or TRT confirms whether any element of the structure has melted.

Planer poly/STI structures

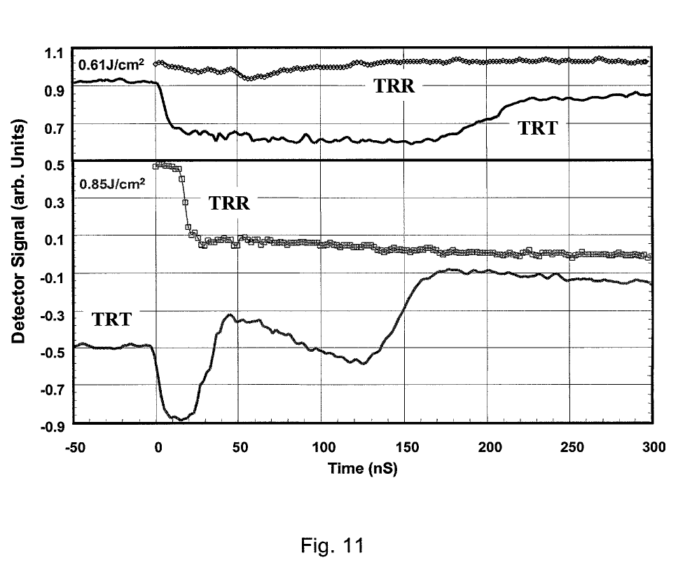

TRR (upper) and TRT (lower) measurements from a planar poly/STI structure, such as structure 160 of FIG. 1A, are shown in FIG. 11. The incident laser pulse is near rectangular, 20 nS FWHM at 748 nm. The two sets of traces correspond to irradiation with the target (0.61J/cm²) and a higher (0.85J/cm²) energy density.

The TRR trace at 0.61J/cm² indicates that no phase changes have occurred during the protocol. The corresponding TRT indicates that long-lived photocarriers are generated in the substrate but overlying layers do not incur structural damage. The model results for this case predict that the maximum temperature reached anywhere in the structure at any time during pulsed laser annealing is less than the melting temperature of any layer. In contrast, the TRR and TRT traces for the 0.85J/cm² case indicate a melt duration longer than 275 nS, consistent with the model prediction for this protocol.

Planar STI structures

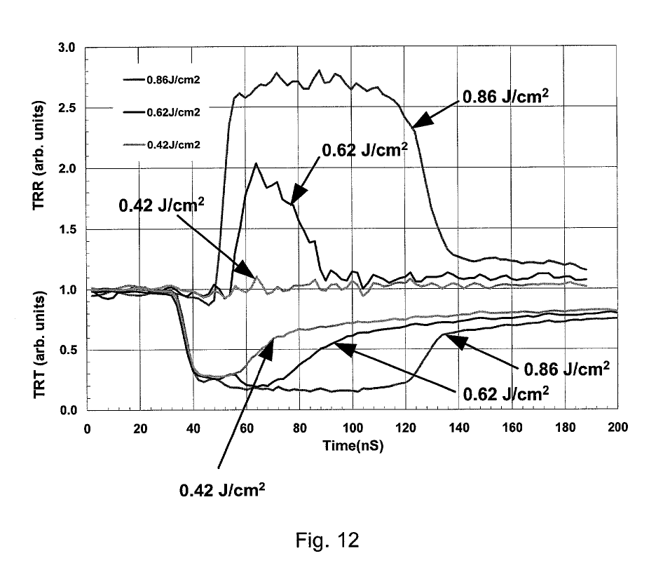

Similar results are shown in FIG. 12 for a shallow trench isolation structure, illustrated by element 164 of FIG. 1A, that has been irradiated with three different energy densities using near rectangular/20 nS/748 nm laser pulse irradiation. At 0.42J/cm², the TRR and TRT data indicate no melt event and the usual transmission decrease due to laser generated photocarriers. At 0.62J/cm², the TRR indicates the onset of melting and the TRT indicates a longer lived concentration of photocarriers in the bulk of the substrate. At 0.85J/cm², the TRR and TRT signals indicate a melt duration of 80 nS. The end of the melt signal in the TRT trace at 130 nS is followed by persistent photogenerated carrier absorption. The melt threshold for this structure is predicted to be 0.61J/cm2, in complete agreement with the measured result.

Other Experimental Methods for Improving Model Predictions

The reflectivity values assigned to the stacked structures and their temperature dependence are the dominant parameters for energy absorption into the structure. Improved values at 300K can be obtained by a simple reflectometer measurement of stacked planar or patterned wafers whose composition and structure are known. The temperature dependence of multilayered stacks is best modeled by fitting calculations from TFOC to the TRR and TRT results for energy densities below the melt threshold. The exercise is to vary the complex index of refraction for the material database in a software package such as TFOC until satisfactory agreement is obtained.

In a similar approach, the complex index is conveniently measured at 300K for any material at most wavelengths of interest using known techniques in spectroscopic ellipsometry. The data provide accurate measures of n and k at low light intensities and serve as a starting point to model the absorption coefficient at high laser intensities. Since a large body of literature exists on theoretical and experimental methods for estimating the dependence of the complex index on temperature, estimates for the temperature dependence of the index at low intensity can be made. These serve as initial estimates for the high intensity index at elevated temperatures. See, e.g., Semiconductors and Semimetals v23, Academic Press, 1984.

IV. Choice of Laser System for Source Drain Extension Anneal

Minimizing Pattern Density Effects

The unique modeling approaches used in the instant invention improve the accuracy of process window predictions for a specified laser annealing protocol. The novel modeling approaches break the two-dimensional heat flow problem into a series of one-dimensional modeling experiments. Furthermore, results of modeling experiments are verified and parameter values for the series of one-dimensional modeling experiments are refined using the physical experiments described above. Based on these advantageous techniques, the pulsed laser annealing parameter space is accurately explored. The results of this exploration indicate that, for the case of a 20 nm amorphized source drain extension implant anneal, the pulse length, wavelength, and pulse shape combination that provides a positive process window is available for λ>650 nm and gaussian pulse shapes with FWHM>5 nS. Available lasers that satisfy these requirements include ruby (694 nm), alexandrite (700<λ<810 nm), Ti:sapphire (700 nm<λ<920 nm), Nd:YAG (1064 nm), or CO2 (10.6 um).

The description of the structures shown in FIGS. 1A through C indicate that the areal density of gate or local interconnect structures may play an important role in the successful transfer of the protocol identified by the current method. As described previously, two-dimensional heat flow effects are only indirectly modeled by the current invention, the suggested approach being to choose protocols that generate similar temperature profiles in adjacent structures. This effect becomes more important as the height and pitch of features on the substrate approach the thermal diffusion length for the process over the pulse duration.

Diffraction effects become important when the height and pitch of the features are comparable to the wavelength of the incident laser pulse. Diffraction from gate structures in modern integrated circuits redistributes the intensity of the laser pulse that is designed to provide uniform illumination. Hot spots in the structure result and can potentially destroy the uniformity of the SDE anneal over varying structure pitches.

Both effects are exacerbated if the laser pulse is short or if the wavelength is too short. Short pulse lengths reduce the effective thermal diffusion length and short wavelength radiation is absorbed within a depth comparable to the feature size (100 nm). From these effects, the optimum pulsed laser annealing protocol in the available parameter space is chosen in favor of longer wavelength and longer pulse length modeled for the given pattern.

Laser System Requirements

Several laser specifications are known. The system is required to have sufficient wavelength, pulse length, pulse shape, and pulse energy stability to remain within the optimum parameter space for the target process. An additional requirement is for uniform illumination at the substrate surface. Modem optical engineering techniques suggest that the multimode cavity operation and wider lasing bandwidth are desirable. Beam homogenization to within one percent over the usable spot area at the substrate usually requires M²>100, where M is the conventional “mode number” of the system.

A pulsed laser annealing system useful for integrated circuit manufacturing preferably delivers sufficient energy to illuminate an entire circuit die on a semiconductor substrate. Current die sizes require that the illuminated area be on the order of 6 cm². From the above, the energy density required for PLA of implants at 532 nm and 748 nm is 0.5J/cm²-0.65J/cm². The total pulse energy for 6 cm² processing is near 4 joules. Allowing for about fifty percent loss in the homogenization and optical delivery systems, the required output pulse energy at the laser approaches 10 joules per pulse.

Of the lasers mentioned at the outset of this section, the ruby and Ti:sapphire lasers are excluded by virtue of the limited pulse energy available. These laser systems are based on the Al₂O₃ crystal system, which does not have a sufficiently high thermal conductivity suitable for operation at this power level. Systems designed with multiple lasers are undesirable based on cost and reliability concerns.

The Nd:YAG laser is also inappropriate because of low pulse energy. For PLA at the >1 um wavelength of this laser, the absorption coefficient in Si, for example, is low (<200 cm−1), and dominated at low temperatures by substrate doping effects (free carrier absorption). The optimum set of laser parameters, even if the energy were available, becomes dependent on the local doping in the device structure. At best, the free carrier absorption effects need to be included in the modeling. At worst, reproducible SDE annealing becomes sensitive to variations in well or halo implant steps prior to formation of the SDE.

We conclude that the optimum wavelength (700 nm-810 mn)/pulse length (5 nS-20 nS)/pulse shape (near rectangular)/pulse energy (10J/pulse) parameters for SDE annealing in modern CMOS microprocessor ICs are provided by an alexandrite laser system.

All references cited herein are incorporated herein by reference in their entirety and for all purposes to the same extent as if each individual publication or patent or patent application was specifically and individually indicated to be incorporated by reference in its entirety for all purposes. The many features and advantages of the present invention are apparent from the detailed specification and thus, it is intended by the appended claims to cover all such features and advantages of the described method which follow in the true spirit and scope of the invention. Further, since numerous modifications and changes will readily occur to those of ordinary skill in the art, it is not desired to limit the invention to the exact construction and operation illustrated and described. Accordingly, all suitable modifications and equivalents may be resorted to as falling within the spirit and scope of the claimed invention.

We claim:

1. A method for modeling an annealing protocol for an implant anneal of a patterned semiconductor substrate, comprising:
accumulating optical and thermal parameters for each sublayer in a plurality of vertically unique one-dimensional layer structures in said patterned semiconductor substrate, said plurality of vertically unique one-dimensional layer structures including a one-dimensional target layer structure and at least one one-dimensional ancillary layer structure;
determining an energy density required for full anneal of said one-dimensional target layer structure using said annealing protocol; and
evaluating, for each sublayer of a one-dimensional ancillary layer structure in said plurality of vertically unique one-dimensional layer structures, whether a temperature reached in the sublayer exceeds the sublayer melting temperature during said annealing protocol when said energy density required for full anneal of said one-dimensional target layer structure is used.

2. The method of claim 1 wherein said determining step and said evaluating step are performed using a finite element analysis model.

3. The method of claim 2 wherein said finite element analysis model couples Beer's law, Fourier's heat equation, and kinetic undercooling approximation.

4. The method of claim 1 wherein said annealing protocol is a pulsed laser annealing protocol.

5. The method of claim 1 wherein said one-dimensional target layer structure represents an implanted region of said patterned semiconductor substrate.

6. The method of claim 5 wherein said implanted region is amorphous.

7. The method of claim 5 wherein said implanted region is a source and drain extension region.

8. The method of claim 1, wherein said one-dimensional ancillary layer structure represents a feature of said patterned semiconductor substrate and the feature is selected from the group consisting of:
a gate,
an exposed shallow trench isolation region, and
polysilicon over a shallow trench isolation region.

9. The method of claim 1 wherein said plurality of unique one-dimensional layer structures is representative of each vertically unique structure in the three dimensional pattern of said patterned semiconductor substrate.

10. A method for finding a process window for the implant anneal of a patterned semiconductor substrate using a predetermined pulsed laser annealing protocol, comprising:
accumulating optical and thermal parameters for each sublayer in a plurality of unique one-dimensional layer structures in said patterned semiconductor substrate, said plurality of vertically unique one-dimensional layer structures including a one-dimensional target layer structure and at least one one-dimensional ancillary layer structure;
determining a minimum energy density required for full anneal of said one-dimensional target layer structure using said predetermined pulsed laser annealing protocol; and
establishing a maximum energy density that does not damage any sublayer in any one-dimensional ancillary layer structure in said plurality of vertically unique one-dimensional layer structures when said predetermined pulsed laser annealing protocol is used; wherein
said process window comprises a range of energy densities bounded by said minimum energy density and said maximum energy density.

11. The method of claim 10 wherein said plurality of unique one-dimensional layer structures is representative of each vertically unique structure in the three dimensional pattern of said substrate.

12. A method for determining a maximum pulse length for the implant anneal of a patterned semiconductor substrate using a predetermined pulsed laser annealing protocol at a given laser wavelength and pulse shape, comprising:
accumulating optical and thermal parameters for each sublayer in a plurality of unique one-dimensional layer structures in said patterned semiconductor substrate, said plurality of vertically unique one-dimensional layer structures including a one-dimensional target layer structure and at least one one-dimensional ancillary layer structure, each said sublayer having a melting temperature Tₘ;
setting a pulse length for said pulsed laser annealing protocol to a first pulse length;
determining a minimum energy density required for fall anneal of said one-dimensional target layer structure using said predetermined pulsed laser annealing protocol at said pulse length;
calculating a maximum temperature (Tₘₐₓ) for a one-dimensional ancillary layer structure in said plurality of vertically unique one-dimensional layer structures, said maximum temperature defined as a maximum temperature at any point z in said one-dimensional ancillary layer structure at any time t during an application of said predetermined pulsed laser annealing protocol using said pulse length and said minimum energy density;
comparing, for each sublayer in said one-dimensional ancillary layer structure, Tₘₐₓ to the Tₘ of said sublayer, wherein
when (i) Tₘₐₓ is about equal to Tₘ for only one sublayer in said one-dimensional ancillary layer structure, (ii) T(z,t) is less than Tₘ for all other sublayers in said one-dimensional ancillary layer structure, and (iii) the regrowth velocity for a melted region of said one-dimensional target layer structure is less than 13 meters per second at said predetermined pulsed laser annealing protocol using said pulse length and said minimum energy density, said pulse length is designated as said maximum pulse length;
when (i) Tₘₐₓ is about equal to Tₘ for only one sublayer in said one-dimensional ancillary layer structure, (ii) Tₘₐₓ is less than Tₘ for all other sublayers in said one-dimensional ancillary layer structure, and (iii) the regrowth velocity for a melted region of said one-dimensional target layer structure is greater than about 10 meters per second at said predetermined pulsed laser annealing protocol using said pulse length and said minimum energy density, a positive process window does not exist for said predetermined pulsed laser annealing protocol at said given laser wavelength and no maximum pulse length is designated;
when Tₘₐₓ is greater than Tₘ for any sublayer in said one-dimensional ancillary layer structure, said pulse length is decreased and said method returns to said calculating step; and
when Tₘₐₓ is less than Tₘ for all sublayers in said one-dimensional ancillary layer structure, said pulse length is increased and said method returns to said calculating step.

13. A method for improving parameter estimates used in the modeling of an implant anneal of a patterned semiconductor substrate with a pulsed laser annealing protocol, comprising:
accumulating a plurality of physical parameters for each type of material in said patterned semiconductor substrate; and
using experimental data to correct a physical parameter in said plurality of physical parameters, wherein
said physical parameter that is corrected is associated with the absorption or reflectivity of laser light by a type of material in said patterned semiconductor substrate.

14. The method of claim 13 wherein said patterned semiconductor substrate is characterized by a minimum technology node of 100 nm or less.

15. The method of claim 13 wherein said patterned semiconductor substrate is characterized by a minimum technology node of 70 nm or less.

16. The method of claim 13 wherein said experimental data is selected from the group consisting of epitaxial regrowth, uniform dopant distribution, abrupt impurity profile, and greater than eighty percent electrical activation.

17. The method of claim 13 wherein:
said physical parameter that is corrected is the absorption coefficient for crystalline silicon; and
said experimental data is obtained from a measurement of the melt threshold energy density of crystalline silicon at a predetermined wavelength.

18. The method of claim 13 wherein:
said physical parameter that is corrected is the thermal conductivity of amorphous silicon; and
said experimental data is obtained from time resolved reflectivity techniques on amorphized silicon wafers.

19. The method of claim 13 wherein:
said physical parameter that is corrected is the reflectivity of a stacked structure in said patterned semiconductor substrate that contains liquid silicon during a pulsed laser anneal; and
said experimental data is obtained using time resolved reflectivity.

20. The method of claim 13 wherein:
said physical parameter that is corrected is the reflectivity of a stacked structure in said patterned semiconductor substrate that contains SiO₂; and
said experimental data is obtained using time resolved reflectivity.

21. A method for optimizing a pulsed laser annealing protocol for an implant anneal of a patterned semiconductor substrate, comprising:
defining a test laser annealing protocol;
determining a first energy density required for full anneal of an implant region in said patterned semiconductor substrate using said test laser annealing protocol;
evaluating whether a feature on said patterned semiconductor substrate is damaged when said test laser annealing protocol is applied with a second energy density, wherein said second energy density is equal to or greater than said first energy density;
adjusting a parameter of said test protocol based on said evaluating step; and
repeating said defining, determining and evaluating steps until a positive process window for said patterned semiconductor substrate is maximized, thereby optimizing said pulsed laser annealing protocol.

22. The method of claim 21 wherein said implant region is amorphous.

23. The method of claim 22 wherein said implant region is a source and drain extension region.

24. The method of claim 21 wherein said patterned semiconductor substrate is characterized by a technology node that is 70 nm or less.

25. The method of claim 21 wherein said parameter that is changed in said adjusting step is a wavelength, pulse length, pulse shape, or second energy density.

26. The method of claim 25 wherein said adjusting step is further determined by an availability of a laser capable of providing a wavelength, pulse length, pulse shape, and second energy density specified by said test laser annealing protocol.

27. The method of claim 26 wherein said laser is capable of delivering an energy density of 6 joules or more per pulse.

28. The method of claim 27 wherein said laser is capable of delivering an energy density of about 6 joules per pulse to about 12 joules per pulse.

29. The method of claim 21 wherein said adjusting step is further determined by a preselected maximum regrowth velocity for said implant region.

30. The method of claim 29 wherein said preselected maximum regrowth velocity is about 13 meters per second or less.

31. The method of claim 30 wherein said preselected maximum regrowth velocity is about 10 meters per second or less.

32. The method of claim 21wherein said adjusting step is further determined by a melting of a feature on said patterned semiconductor substrate.

33. The method of claim 32 wherein said feature is a gate, a polysilicon over a shallow trench isolation region, or an exposed shallow trench isolation region.

34. The method of claim 21 wherein said adjusting step is further determined by a requirement of approximately uniform processing of a plurality of surface features on said patterned semiconductor substrate, each surface feature in said plurality of surface features having a different pitch.

35. The method of claim 21 wherein said patterned semiconductor substrate is characterized by a technology node of 100 nm or less.

36. A method for source drain extension annealing of a patterned semiconductor substrate, comprising:
exposing said patterned semiconductor substrate to a laser annealing protocol; wherein:
the laser used in said laser annealing protocol has a wavelength selected from the range of 700 nm to 810 nm.

37. The method of claim 36 wherein said patterned semiconductor substrate is characterized by a technology node of 100 nm or less.

38. The method of claim 36 wherein said wavelength is selected from the range of 748 nm to 810 nm.

39. The method of claim 36 wherein said semiconductor substrate is a silicon CMOS.

40. The method of claim 36 wherein said laser annealing protocol comprises a single laser pulse that is selected from a pulse length range, wherein:
a lower boundary of said pulse length range is determined by a requirement that a regrowth velocity for a region of said patterned semiconductor substrate that is melted by said laser annealing protocol is less than 13 meters per second; and
said upper boundary of said pulse length range is determined by a requirement that said laser annealing protocol exhibits a positive process margin.

41. The method of claim 36 wherein said laser annealing protocol comprises a single pulse having a pulse shape that approximates a rectangular shape.

42. The method of claim 36 wherein said laser annealing protocol comprises a single pulse having a pulse shape that is defined by a front edge and a back edge, wherein the front edge and the back edge of said pulse shape are more abrupt than the front edge and back edge of a corresponding gaussian pulse shape.

43. The method of claim 36 wherein the laser used in said laser annealing protocol of said exposing step has an output pulse energy of greater than 6 joules.

44. The method of claim 36 wherein the laser used in said laser annealing protocol of said exposing step has a pulse repetition rate of about 10 Hz or greater.

45. A pulsed alexandrite laser system for use in shallow source drain annealing of a patterned silicon substrate, said laser system characterized by a fall width half maximum pulse length selected from the range of 5 nanoseconds to 20 nanoseconds and an output pulse energy of greater than about 6 joules per pulse.

46. The pulsed alexandrite laser system of claim 45 wherein said patterned silicon substrate has a technology node of 100 nm or less.

47. The pulsed alexandrite laser system of claim 45 wherein said system delivers a pulse shape that approximates a rectangular shape.

48. The pulsed alexandrite laser system of claim 45 wherein said system delivers a laser pulse, the pulse shape of said laser pulse defined by a front edge and a back edge, wherein the front edge and the back edge of said pulse shape are more abrupt than the front edge and back edge of a corresponding gaussian pulse shape.

49. The pulsed alexandrite laser system of claim 45 wherein said output pulse energy is equivalent to about 1 joules per square centimeter of said patterned silicon substrate or greater.

50. The pulsed alexandrite laser system of claim 45 wherein an output pulse energy that is delivered to said patterned silicon substrate is about 0.5 joules per square centimeter or greater.
